(19) United States
(12) Patent Application Publication
(10) Pub. No.: US 2021/0286267 A1
(43) Pub. Date: Sep. 16, 2021

(54) COMPOSITION, RESIST UNDERLAYER FILM, AND RESIST PATTERN-FORMING METHOD

(71) Applicant: JSR CORPORATION, Tokyo (JP)

(72) Inventors: Tsubasa Abe, Tokyo (JP); Gouji Wakamatsu, Seongnam-si (KR)

(73) Assignee: JSR CORPORATION, Tokyo (JP)

(21) Appl. No.: 17/331,757

(22) Filed: May 27, 2021

Related U.S. Application Data
(63) Continuation of application No. PCT/JP2019/046194, filed on Nov. 26, 2019.

(30) Foreign Application Priority Data
Nov. 29, 2018 (JP) 2018-224149

(51) Int. Cl. G03F 7/11; C08G 8/24; C09D 161/06; C08G 8/20; C09D 161/12; C08F 212/32; C09D 125/02; C08F 220/22; C09D 133/16

(52) U.S. Cl. CPC G03F 7/11; C08G 8/24; C09D 161/06; C08G 8/20; C09D 133/16; C08F 212/32; C09D 125/02; C08F 220/22; C09D 161/12

(57) ABSTRACT

A composition contains: an aromatic ring-containing compound; a fluorine atom-containing polymer; and an organic solvent. The fluorine atom-containing polymer has: a first structural unit represented by formula (1); and a second structural unit represented by formula (2). In the formula (1), R¹ represents a fluorine atom-containing monovalent organic group having 1 to 20 carbon atoms; and R² represents a hydrogen atom or a monovalent hydrocarbon group having 1 to 20 carbon atoms. In the formula (2), R³ represents a monovalent hydrocarbon group having 1 to 20 carbon atoms; and R⁴ represents a hydrogen atom or a monovalent hydrocarbon group having 1 to 20 carbon atoms.

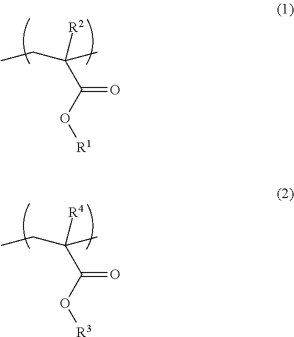

### CROSS-REFERENCE TO RELATED APPLICATIONS

The present application is a continuation application of International Application No. PCT/JP2019/046194, filed Nov. 26, 2019, which claims priority to Japanese Patent Application No. 2018-224149, filed Nov. 29, 2018. The contents of these applications are incorporated herein by reference in their entirety.

### BACKGROUND OF THE INVENTION

### Field of the Invention

The present invention relates to a composition, a resist underlayer film, and a resist pattern-forming method.

### Description of the Related Art

In manufacturing semiconductor devices, a method has been employed in which a resist underlayer film is formed directly or indirectly on an upper face side of a substrate, from a composition for forming a resist underlayer film, and a resist pattern is formed directly or indirectly on an upper face side of the resist underlayer film by using a composition for forming a resist film or the like. The resist underlayer film is etched by using the resist pattern as a mask, and further, the substrate can be etched by using the resultant resist underlayer film pattern as a mask.

Materials for use in such a composition for forming a resist underlayer film have been variously investigated (see Japanese Unexamined Patent Application, Publication No. 2013-83833).

### SUMMARY OF THE INVENTION

According to an aspect of the present invention, a composition includes: an aromatic ring-containing compound; a fluorine atom-containing polymer; and an organic solvent. The fluorine atom-containing polymer includes: a first structural unit represented by formula (1); and a second structural unit represented by formula (2).

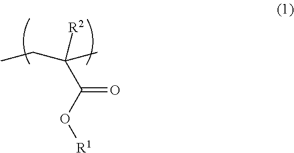

In the formula (1), R¹ represents a fluorine atom-containing monovalent organic group having 1 to 20 carbon atoms; and R² represents a hydrogen atom or a monovalent hydrocarbon group having 1 to 20 carbon atoms.

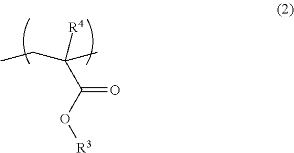

In the formula (2), R³ represents a monovalent hydrocarbon group having 1 to 20 carbon atoms; and R⁴ represents a hydrogen atom or a monovalent hydrocarbon group having 1 to 20 carbon atoms.

According to another aspect of the present invention, a resist underlayer film is formed from the above-mentioned composition.

According to a further aspect of the present invention, a resist pattern-forming method includes applying the above-mentioned composition directly or indirectly on an upper face side of a substrate to form a resist underlayer film. A silicon-containing film is formed directly or indirectly on an upper face side of the resist underlayer film. A composition for forming a resist film is applied directly or indirectly on an upper face side of the silicon-containing film to form a resist film. The resist film is exposed to a radioactive ray. The resist film exposed is developed.

### BRIEF DESCRIPTION OF THE DRAWING

FIG. 1s a schematic cross-sectional view for illustrating a flatness evaluation method.

### DESCRIPTION OF EMBODIMENTS

Recently, substrates having multiple types of trenches, particularly trenches with aspect ratios that are different from one another, have been employed. In this case, the composition for forming a resist underlayer film is required to be capable of forming a resist underlayer film superior in an embedding property and flatness.

According to one embodiment of the invention, a composition contains:

an aromatic ring-containing compound;

a fluorine atom-containing polymer; and

an organic solvent, wherein

the fluorine atom-containing polymer has: a first structural unit represented by the following formula (1); and a second structural unit represented by the following formula (2):

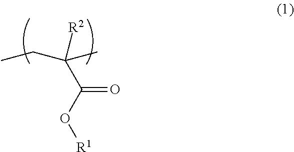

wherein,
in the formula (1), R¹ represents a fluorine atom-containing monovalent organic group having 1 to 20 carbon atoms; and R² represents a hydrogen atom or a monovalent hydrocarbon group having 1 to 20 carbon atoms, and

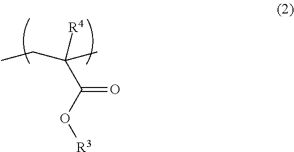

in the formula (2), R³ represents a monovalent hydrocarbon group having 1 to 20 carbon atoms; and R⁴ represents a hydrogen atom or a monovalent hydrocarbon group having 1 to 20 carbon atoms.

According to another embodiment of the invention, a resist underlayer film is formed from the composition of the one embodiment of the invention.

According to yet another embodiment of the invention, a resist pattern-forming method includes:

applying directly or indirectly on an upper face side of a substrate, the composition of the one embodiment of the invention to form a resist underlayer film;

forming a silicon-containing film directly or indirectly on an upper face side of the resist underlayer film;

applying a composition for forming a resist film directly or indirectly on an upper face side of the silicon-containing film to form a resist film;

exposing the resist film to a radioactive ray; and

developing the resist film exposed.

According to the composition of the one embodiment of the present invention, a resist underlayer film superior in the embedding property and flatness can be formed. The resist underlayer film of the another embodiment of the present invention is superior in the embedding property and flatness. According to the resist pattern-forming method of the yet another embodiment of the present invention, a favorable resist pattern can be formed by using such a resist underlayer film, being superior in the embedding property and flatness. Therefore, these can be suitably used in the manufacture of semiconductor devices and the like, in which further progress of miniaturization is expected in the future. Hereinafter, the embodiments of the present invention will be explained in detail.

### Composition for Forming Resist Underlayer Film

According to one embodiment of the present invention, a composition for forming a resist underlayer film contains: an aromatic ring-containing compound (hereinafter, may be also referred to as “(A) compound” or “compound (A)”); a fluorine atom-containing polymer (hereinafter, may be also referred to as “(B) polymer” or “polymer (B)”; and an organic solvent (hereinafter, may be also referred to as “(C) organic solvent” or “organic solvent (C)”, wherein the polymer (B) has: a first structural unit represented by formula (1) (hereinafter, may be also referred to as “structural unit (I)”); and a second structural unit represented by formula (2) (hereinafter, may be also referred to as “structural unit (II)”).

In addition to the compound (A), the polymer (B), and the organic solvent (C), the composition for forming a resist underlayer film preferably also contains an acid generating agent (hereinafter, may be also referred to as “(D) acid generating agent” or “acid generating agent (D)”) and/or a crosslinking agent (hereinafter, may be also referred to as “(E) crosslinking agent” or “crosslinking agent (E)”), and may also contain, within a range not leading to impairment of the effects of the present invention, other optional component(s).

The composition enables forming a resist underlayer film superior in the embedding property and flatness due to the composition containing the compound (A), the polymer (B), and the organic solvent (C), and the polymer (B) having the structural unit (I) and the structural unit (II). Although not necessarily clarified and without wishing to be bound by any theory, the reason for achieving the effects described above due to the composition having the constitution described above may be supposed as in the following. For example, it is considered that addition of the polymer (B), which has a specific structure including the structural unit (I) and the structural unit (II), to the aromatic ring-containing compound (A) improves flowability and the like of the composition in a step of applying the composition.

Hereinafter, each component will be described.

### (A) Compound

The compound (A) contains an aromatic ring. The compound (A) can be used without any particular limitation as long as it contains the aromatic ring. The compound (A) may be used either alone of one type, or in a combination of two or more types thereof.

Examples of the aromatic ring include:

aromatic carbon rings such as a benzene ring, a naphthalene ring, an anthracene ring, an indene ring, a pyrene ring, a fluorenylidenebiphenyl ring, and a fluorenylidenebinaphthalene ring;

aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine ring; and the like. Of these, the aromatic carbon ring is preferred.

The compound (A) is exemplified by a polymer (hereinafter, may be also referred to as “(A) polymer” or “polymer (A)”) having a structural unit containing an aromatic ring; an aromatic ring-containing compound; and the like. The “polymer” as referred to herein means a compound having at least two structural units. The “aromatic ring-containing compound” as referred to herein means a compound containing an aromatic ring, and having one structural unit. A molecular weight of the aromatic ring-compound compound is, for example, no less than 300 and no greater than 3,000. With regard to the composition for forming a resist underlayer film, when the polymer (A) is used as the compound (A), coating characteristics can be further improved.

The polymer (A) is exemplified by a polymer containing an aromatic ring on a main chain thereof; a polymer not containing an aromatic ring on a main chain thereof, but containing an aromatic ring on a side chain thereof; and the like. The “main chain” as referred to herein means a longest chain among chains constituted from atoms in the polymer. The “side chain” as referred to herein means a chain other than the longest chain, among the chains constituted from the atoms in the polymer.

The polymer (A) may be a polycondensation compound, a compound obtained by a reaction other than polycondensation, or the like.

Examples of the polymer (A) include a novolac resin, a resol resin, a styrene resin, an acenaphthylene resin, an indene resin, an arylene resin, a triazene resin, a calixarene resin, and the like.

Novolac Resin

The novolac resin is a resin obtained by allowing a phenolic compound to react with an aldehyde compound, a divinyl compound, or the like using an acidic catalyst. A plurality of phenolic compounds may be mixed with an aldehyde compound, a divinyl compound, or the like and allowed to react.

Examples of the phenolic compound include:

phenols such as phenol, cresol, xylenol, resorcinol, bisphenol A, p-tert-butylphenol, p-octylphenol, 9,9-bis(4-hydroxyphenyl)fluorene, 9,9-bis(3-hydroxyphenyl)fluorene, and 4,4′-(α-methylbenzylidene)bisphenol;

naphthols such as α-naphthol, β-naphthol, 1,5-dihydroxynaphthalene, 2,7-dihydroxynaphthalene, and 9,9-bis(6-hydroxynaphthyl)fluorene;

anthrols such as 9-anthrol;

pyrenols such as 1-hydroxypyrene and 2-hydroxypyrene; and the like.

Examples of the aldehyde compound include:

aldehydes such as formaldehyde, benzaldehyde, 1-naphthaldehyde, 2-naphthaldehyde, and 1-formylpyrene;

aldehyde sources such as paraformaldehyde and trioxane; and the like.

Examples of the divinyl compound include divinylbenzene, dicyclopentadiene, tetrahydroindene, 4-vinylcyclohexene, 5-vinylnorborna-2-ene, divinylpyrene, limonene, 5-vinylnorbornadiene, and the like.

Examples of the novolac resin include: a resin having a structural unit derived from phenol and formaldehyde; a resin having a structural unit derived from cresol and formaldehyde; a resin having a structural unit derived from dihydroxynaphthalene and formaldehyde; a resin having a structural unit derived from fluorene bisphenol and formaldehyde; a resin having a structural unit derived from fluorene bisnaphthol and formaldehyde; a resin having a structural unit derived from hydroxypyrene and formaldehyde; a resin having a structural unit derived from hydroxypyrene and naphthaldehyde; a resin having a structural unit derived from 4,4′-(α-methylbenzylidene) bisphenol and formaldehyde; a resin having a structural unit derived from a phenol compound and formylpyrene; a resin being a combination thereof; and a resin obtained by substituting a part or all of hydrogen atoms of the phenolic hydroxyl groups of any of these resins with a propargyl group or the like; and the like.

Resol Resin

The resol resin is a resin obtained by allowing a phenolic compound to react with an aldehyde compound using an alkaline catalyst.

Styrene Resin

The styrene resin is a resin having a structural unit derived from a compound containing an aromatic ring and a polymerizable carbon-carbon double bond. Aside from the aforementioned structural units, the styrene resin may have a structural unit derived from an acrylic monomer, a vinyl ether, or the like.

Examples of the styrene resin include polystyrene, polyvinylnaphthalene, polyhydroxystyrene, polyphenyl (meth)acrylate, a resin being a combination thereof, and the like.

Acenaphthylene Resin

The acenaphthylene resin is a resin having a structural unit derived from a compound that includes an acenaphthylene skeleton.

Examples of the acenaphthylene resin include a copolymer of acenaphthylene and hydroxymethylacenaphthylene, and the like.

Indene Resin

The indene resin is a resin having a structural unit derived from a compound that includes an indene skeleton.

Arylene Resin

The arylene resin is a resin having a structural unit derived from a compound that includes an arylene skeleton. The arylene skeleton is exemplified by a phenylene skeleton, a naphthylene skeleton, a biphenylene skeleton, and the like.

Examples of the arylene resin include polyarylene ether, polyarylene sulfide, polyarylene ether sulfone, polyarylene ether ketone, a resin having a structural unit that includes a biphenylene skeleton, a resin having a structural that includes a biphenylene skeleton and a structural unit derived from a compound that includes an acenaphthylene skeleton, and the like.

Triazene Resin

The triazene resin is a resin having a structural unit derived from a compound that includes a triazene skeleton.

Examples of the compound that includes the triazene skeleton include a melamine compound, a cyanuric acid compound, and the like.

In the case of the polymer (A) being the novolac resin, the resol resin, the styrene resin, the acenaphthylene resin, the indene resin, the arylene resin, or the triazene resin, the lower limit of a polystyrene-equivalent weight average molecular weight (Mw) of the polymer (A) as determined by gel permeation chromatography (GPC) is preferably 1,000, more preferably 2,000, still more preferably 3,000, and particularly preferably 4,000. Furthermore, the upper limit of the Mw is preferably 100,000, more preferably 60,000, still more preferably 30,000, and particularly preferably 15,000. When the Mw of the polymer (A) falls within the above range, the embedding property and flatness of the resist underlayer film can be further improved.

The upper limit of Mw/Mn (“Mn” as referred to herein means a polystyrene-equivalent number average molecular weight as determined by GPC) of the polymer (A) is preferably 5, more preferably 3, and still more preferably 2. The lower limit of the Mw/Mn is typically 1, and preferably 1.2.

As referred to herein, the Mw and the Mn of the polymer are values measured by gel permeation chromatography (detector: differential refractometer) using GPC columns (“G2000 HXL”×2, “G3000 HXL”×1, and “G4000 HXL”×1, available from Tosoh Corporation) under an analytical conditions involving a flow rate of 1.0 mL/min, an elution solvent of tetrahydrofuran, and a column temperature of 40° C., with mono-dispersed polystyrene as a standard.

Calixarene Resin

The calixarene resin is a cyclic oligomer derived from a plurality of aromatic rings to which a hydroxy group bonds, through linking to be cyclic via a hydrocarbon group, or the cyclic oligomer from which a part or all of hydrogen atoms included in the hydroxy group, the aromatic ring, and the hydrocarbon group are substituted.

Examples of the calixarene resin include: a cyclic tetramer to dodecamer formed from formaldehyde and a phenol compound such as phenol or naphthol; a cyclic tetramer to dodecamer formed from a benzaldehyde compound and a phenol compound such as phenol or naphthol; a resin obtained by substituting a hydrogen atom of the phenolic hydroxyl groups contained in these cyclic compounds with a propargyl group or the like; and the like.

The lower limit of a molecular weight of the calixarene resin is preferably 500, more preferably 700, and still more preferably 1,000. The upper limit of the molecular weight is preferably 5,000, more preferably 3,000, and still more preferably 1,500.

The compound (A) preferably includes a hydroxyl group. Examples of the hydroxyl group include a phenolic hydroxyl group, an alcoholic hydroxyl group, and the like. When the compound (A) includes the hydroxyl group, a crosslinking reaction of the compound (A) can be promoted by the acid generating agent (D), the crosslinking agent (E), and the like, described later.

The lower limit of a proportion of the compound (A) with respect to all components other than the organic solvent (C) in the composition for forming a resist underlayer film is preferably 20% by mass, more preferably 35% by mass, still more preferably 45% by mass, and particularly preferably 55% by mass. The upper limit of the proportion is preferably 99% by mass, more preferably 95% by mass, still more preferably 90% by mass, and particularly preferably 85% by mass.

The lower limit of a proportion of the compound (A) in the composition for forming a resist underlayer film is preferably 0.1% by mass, more preferably 1% by mass, and still more preferably 2% by mass. The upper limit of the proportion is preferably 50% by mass, more preferably 20% by mass, and still more preferably 10% by mass.

Synthesis Procedure of Compound (A)

The compound (A) may be synthesized by a well-known procedure, or a commercially available product may be used.

### (B) Polymer

The polymer (B) is a fluorine atom-containing polymer which has the structural unit (I) and the structural unit (II). In addition to the structural unit (I) and the structural unit (II), the polymer (B) may also have other structural unit(s).

Each structural unit will be described below.

Structural Unit (I)

The structural unit (I) is a structural unit represented by the following formula (I).

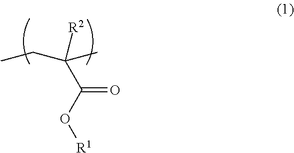

In the above formula (1), R¹ represents a fluorine atom-containing monovalent organic group having 1 to 20 carbon atoms; and R² represents a hydrogen atom or a monovalent hydrocarbon group having 1 to 20 carbon atoms.

The “organic group” as referred to herein means a group that includes at least one carbon atom. The monovalent organic group having 1 to 20 carbon atoms is exemplified by: a monovalent hydrocarbon group having 1 to 20 carbon atoms; a group that includes a divalent hetero atom-containing group between two adjacent carbon atoms of the monovalent hydrocarbon group having 1 to 20 carbon atoms; a group obtained by substituting with a monovalent hetero atom-containing group, a part or all of hydrogen atoms included in the monovalent hydrocarbon group having 1 to 20 carbon atoms or the group that includes a divalent hetero atom-containing group; and the like.

Examples of the monovalent hydrocarbon group having 1 to 20 carbon atoms include:

chain hydrocarbon groups, e.g., alkyl groups such as a methyl group, an ethyl group, a propyl group, a butyl group, and a pentyl group; alkenyl groups such as an ethenyl group, a propenyl group, and a butenyl group; and alkynyl groups such as an ethynyl group, a propynyl group, and a butynyl group;

alicyclic hydrocarbon groups, e.g., cycloalkyl groups such as a cyclopentyl group and a cyclohexyl group; cycloalkenyl groups such as a cyclopropenyl group, a cyclopentenyl group, and a cyclohexenyl group; and bridged cyclic hydrocarbon groups such as a norbornyl group and an adamantyl group;

aromatic hydrocarbon groups, e.g., aryl groups such as a phenyl group, a tolyl group, a xylyl group, and a naphthyl group; and aralkyl groups such as a benzyl group, a phenethyl group, and a naphthylmethyl group; and the like.

Examples of the divalent hetero atom-containing group include —CO—, —CS—, —NH—, —O—, —S—, a combination thereof, and the like.

Examples of the monovalent hetero atom-containing group include a hydroxy group, a sulfanyl group, a cyano group, a nitro group, a halogen atom, and the like.

The fluorine atom-containing monovalent organic group having 1 to 20 carbon atoms represented by R¹ is exemplified by a group obtained by substituting with a fluorine atom, a part or all of hydrogen atoms contained in the monovalent group having 1 to 20 carbon atoms exemplified above, and the like.

Specific examples of the fluorine atom-containing monovalent organic group having 1 to 20 carbon atoms include:

fluorinated hydrocarbon groups such as:
fluorinated chain hydrocarbon groups, e.g., fluorinated alkyl groups such as a trifluoromethyl group, a 2,2,2-trifluoroethyl group, a pentafluoroethyl group, a 2,2,3,3,3-pentafluoropropan-1-yl group, a 1,1,1,3,3,3-hexafluoropropan-2-yl group, a heptafluoropropan-1-yl group, a 2,2,3,3,4,4,4-heptafluorobutan-1-yl group, a nonafluorobutan-1-yl group, a 3,3,4,4,5,5,6,6,6-nonafluorohexan-1-yl group, and a tridecafluorohexan-1-yl group;
fluorinated alicyclic hydrocarbon groups, e.g., fluorinated cycloalkyl groups such as an undecafluorocyclohexan-1-yl group and an undecafluorocyclohexan-1-yl methyl group;
fluorinated aromatic hydrocarbon groups, e.g., fluorinated aryl groups such as a 2,4,6-trifluorophenyl group and a pentafluorophenyl group; and fluorinated aralkyl groups such as a pentafluorobenzyl group,

groups containing an oxygen atom and a fluorine atom such as:
a group containing an oxo group and a fluorine atom, e.g., a 4,4,4-trifluoro-3-oxobutan-1-yl group;
a group containing an ether group and a fluorine atom, e.g., a 4,4,5,5,6,6,6-heptafluoro-3-oxahexan-1-yl group;
a group containing a hydroxy group and a fluorine atom, e.g., a 2-hydroxy-2-trifluoromethyl-3,3,3-trifluoropropan-1-yl group, a 4-hydroxy-4-trifluoromethyl-5,5,5-trifluoropentan-2-yl group, and a 3,5-di(1-hydroxy-1-trifluoromethyl-2,2,2-trifluoroethyl)cyclohexan-1-yl group; and the like.

R¹ represents preferably the fluorinated hydrocarbon group, more preferably the fluorinated chain hydrocarbon group, still more preferably the fluorinated alkyl group, and particularly preferably a 2,2,2-trifluoroethyl group or a 1,1,1,3,3,3-hexafluoropropan-2-yl group.

Examples of the monovalent hydrocarbon group having 1 to 20 carbon atoms which may be represented by R² include groups similar to those exemplified above as the monovalent hydrocarbon group having 1 to 20 carbon atoms, and the like.

R² represents preferably a hydrogen atom or the chain hydrocarbon group, more preferably a hydrogen atom or the alkyl group, and still more preferably a hydrogen atom or a methyl group.

Examples of the structural unit (I) include structural units (hereinafter, may be also referred to as “structural units (I-1) to (I-8)”) represented by the following formulae (1-1) to (1-8), and the like.

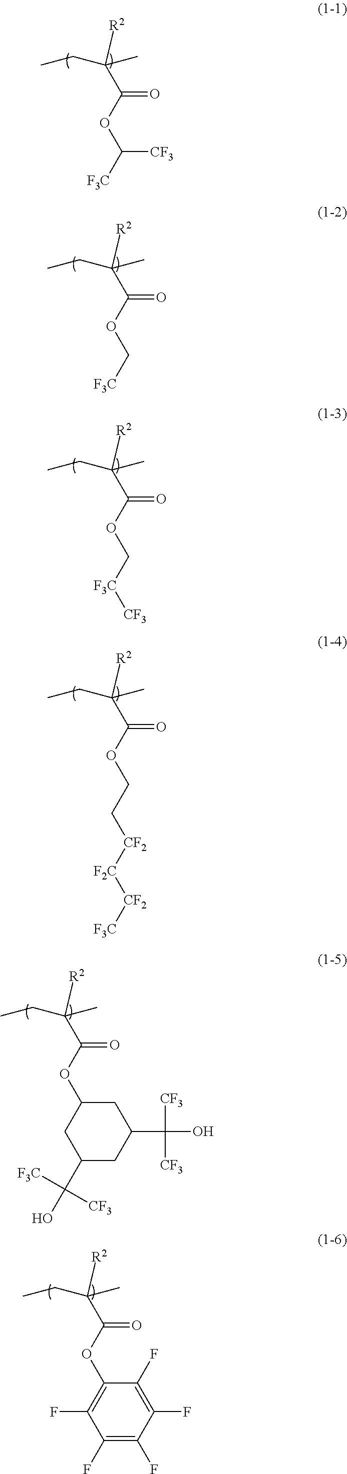

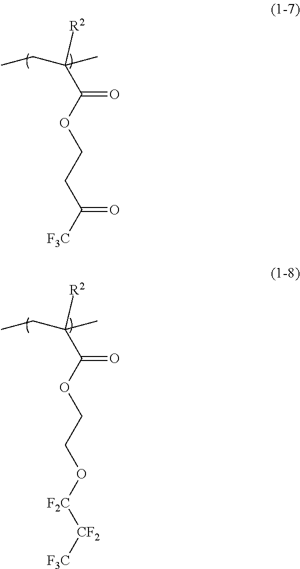

In the above formulae (1-1) to (1-8), R² is as defined in the above formula (1).

The structural unit (I) is preferably the structural unit (I-1) or the structural unit (I-2).

The lower limit of a proportion of the structural unit (I) contained with respect to total structural units constituting the polymer (B) is preferably 1 mol %, more preferably 10 mol %, still more preferably 20 mol %, and particularly preferably 40 mol %. The upper limit of the proportion is preferably 99 mol %, more preferably 90 mol %, still more preferably 80 mol %, and particularly preferably 75 mol %. When the proportion of the structural unit (I) falls within the above range, the embedding property and flatness of the resist underlayer film can be further improved.

Structural Unit (II)

The structural unit (II) is a structural unit represented by the following formula (2).

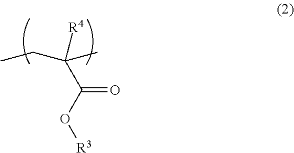

In the above formula (2), R³ represents a monovalent hydrocarbon group having 1 to 20 carbon atoms; and R⁴ represents a hydrogen atom or a monovalent hydrocarbon group having 1 to 20 carbon atoms.

Examples of the monovalent hydrocarbon group having 1 to 20 carbon atoms which may be represented by each of R³ and R⁴ include groups similar to those exemplified above as the monovalent hydrocarbon group having 1 to 20 carbon atoms, and the like.

R³ represents preferably the chain hydrocarbon group, more preferably the alkyl group, and still more preferably a butan-1-yl group or a 2-ethylhexan-1-yl group.

R⁴ represents preferably a hydrogen atom or the chain hydrocarbon group, more preferably a hydrogen atom or the alkyl group, and still more preferably a hydrogen atom or a methyl group.

Examples of the structural unit (II) include structural units (hereinafter, may be also referred to as “structural units (II-1) to (II-8)”) represented by the following formulae (2-1) to (2-8), and the like.

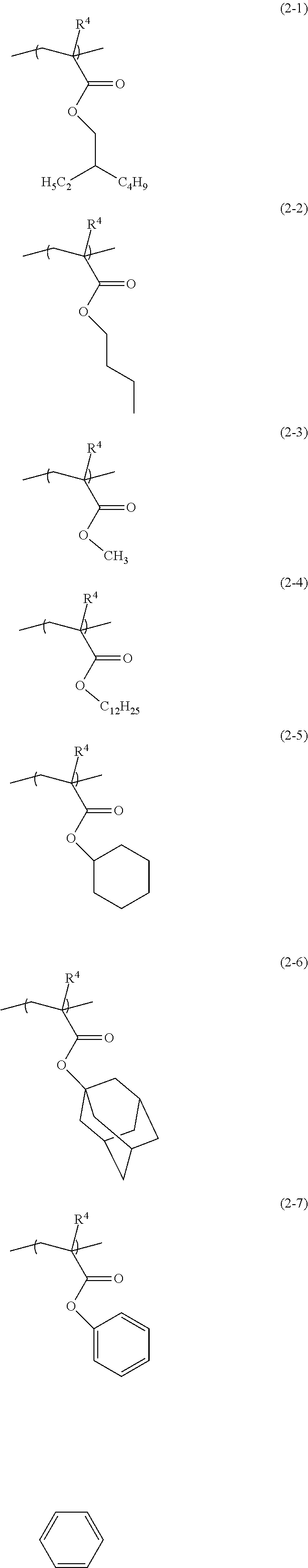

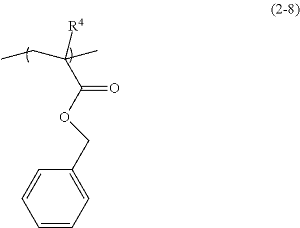

In the above formulae (2-1) to (2-8), R⁴ is as defined in the above formula (2).

The structural unit (II) is preferably the structural unit (II-1) or the structural unit (II-2).

The lower limit of a proportion of the structural unit (II) contained with respect to total structural units constituting the polymer (B) is preferably 1 mol %, more preferably 5 mol %, still more preferably 10 mol %, and particularly preferably 20 mol %. The upper limit of the proportion is preferably 99 mol %, more preferably 90 mol %, still more preferably 75 mol %, and particularly preferably 60 mol %. When the proportion of the structural unit (II) falls within the above range, the embedding property and flatness of the resist underlayer film can be further improved.

Other Structural Unit(s)

The other structural unit(s) may be exemplified by a structural unit derived from a (meth)acrylic acid ester, a structural unit derived from (meth)acrylic acid, a structural unit derived from an acenaphthylene compound, and the like.

In the case in which the polymer (B) has the other structural unit(s), the upper limit of a proportion of the other structural unit(s) contained with respect to total structural units constituting the polymer (B) is preferably 20 mol %, and more preferably 5 mol %. The proportion of the other structural unit(s) contained in the polymer (B) may be 0 mol %.

The lower limit of a weight average molecular weight (Mw) of the polymer (B) is preferably 1,000, more preferably 2,000, still more preferably 3,000, and particularly preferably 4,000. The upper limit of the Mw is preferably 100,000, more preferably 50,000, still more preferably 30,000, and particularly preferably 20,000. When the Mw of the polymer (B) falls within the above range, the embedding property and flatness of the resist underlayer film can be further improved.

The upper limit of the Mw/Mn of the polymer (B) is preferably 5, more preferably 3, and still more preferably 2.5. The lower limit of the Mw/Mn is typically 1, and preferably 1.2.

The lower limit of a proportion of the polymer (B) with respect to total components other than the organic solvent (C) in the composition for forming a resist underlayer film is preferably 1% by mass, more preferably 3% by mass, still more preferably 5% by mass, particularly preferably 10% by mass, further particularly preferably 15% by mass, and most preferably 20% by mass. The upper limit of the proportion is preferably 70% by mass, more preferably 65% by mass, still more preferably 60% by mass, particularly preferably 55% by mass, further particularly preferably 50% by mass, and most preferably 40% by mass.

The lower limit of a proportion of the polymer (B) in the composition for forming a resist underlayer film is preferably 0.01% by mass, more preferably 0.1% by mass, and still more preferably 1% by mass. The upper limit of the proportion is preferably 50% by mass, more preferably 20% by mass, and still more preferably 10% by mass.

The lower limit of a content of the polymer (B) with respect to 100 parts by mass of the compound (A) is preferably 1 part by mass, more preferably 3 parts by mass, still more preferably 5 parts by mass, particularly preferably 10 parts by mass, further particularly preferably 15 parts by mass, and most preferably 25 parts by mass. The upper limit of the content is preferably 200 parts by mass, more preferably 175 parts by mass, still more preferably 150 parts by mass, particularly preferably 125 parts by mass, further particularly preferably 100 parts by mass, and most preferably 75 parts by mass.

When the proportion or the content of the polymer (B) falls within the above ranges, the embedding property and flatness of the resist underlayer film can be further improved.

Synthesis Procedure of Polymer (B)

The polymer (B) can be synthesized by polymerization in accordance with a well-known method using, for example, each of a monomer that gives the structural unit (I), a monomer that gives the structural unit (II), and, as needed, monomer(s) that give(s) the other structural unit(s) in a usage amount that gives each structural unit in a certain proportion.

### (C) Organic Solvent

The organic solvent (C) is not particularly limited as long as it is capable of dissolving or dispersing the compound (A), the polymer (B), and the optional component(s), which is/are contained as needed.

The organic solvent (C) is exemplified by an alcohol solvent, a ketone solvent, an ether solvent, an ester solvent, a nitrogen-containing solvent, a hydrocarbon solvent, and the like. The organic solvent (C) may be used either alone of one type, or in a combination of two or more types thereof.

Examples of the alcohol solvent include: monohydric alcohol solvents such as methanol, ethanol, and n-propanol; polyhydric alcohol solvents such as ethylene glycol and 1,2-propylene glycol; and the like.

Examples of the ketone solvent include: chain ketone solvents such as methyl ethyl ketone and methyl isobutyl ketone; cyclic ketone solvents such as cyclohexanone; and the like.

Examples of the ether solvent include: polyhydric alcohol ether solvents, e.g., chain ether solvents such as n-butyl ether, and cyclic ether solvents such as tetrahydrofuran and 1,4-dioxane; polyhydric alcohol partial ether solvents such as diethylene glycol monomethyl ether; and the like.

Examples of the ester solvent include: carbonate solvents such as diethyl carbonate; acetic acid monoester solvents such as methyl acetate and ethyl acetate; lactone solvents such as γ-butyrolactone; polyhydric alcohol partial ether carboxylate solvents such as diethylene glycol monomethyl ether acetate and propylene glycol monomethyl ether acetate; lactic acid ester solvents such as methyl lactate and ethyl lactate; and the like.

Examples of the nitrogen-containing solvent include: chain nitrogen-containing solvents such as N,N-dimethylacetamide; cyclic nitrogen-containing solvents such as N-methylpyrrolidone; and the like.

Examples of the hydrocarbon solvent include aliphatic hydrocarbon solvents such as decalin; aromatic hydrocarbon solvents such as toluene; and the like.

The organic solvent (C) is preferably the ester solvent, more preferably the polyhydric alcohol partial ether carboxylate solvent, and still more preferably propylene glycol monomethyl ether acetate.

The lower limit of a proportion of the organic solvent (C) in the composition for forming a resist underlayer film is preferably 50% by mass, more preferably 60% by mass, and still more preferably 70% by mass. The upper limit of the proportion is preferably 99.9% by mass, more preferably 99% by mass, and still more preferably 95% by mass.

### (D) Acid Generating Agent

The acid generating agent (D) is a component which generates an acid by an action of a radioactive ray or heat. When the composition for forming a resist underlayer film contains the acid generating agent (D), a crosslinking reaction of the compound (A) and the like is promoted by the acid generated, thereby enabling solvent resistance of the resist underlayer film to be further improved.

The acid generating agent (D) is exemplified by an onium salt compound, an N-sulfonyloxyimide compound, and the like.

Examples of the onium salt compound include:

sulfonium salts such as triphenylsulfonium trifluoromethanesulfonate, triphenylsulfonium 2-(adamantan-1-ylcarbonyloxy)-1,1,3,3,3-pentafluoropropane-1-sulfonate, triphenylsulfonium norbornanesultone-2-yloxycarbonyldifluoromethanesulfonate, triphenylsulfonium piperidin-1-ylsulfonyl-1,1,2,2,3,3-hexafluoropropane-1-sulfonate, triphenylsulfonium adamantan-1-yloxycarbonyldifluoromethanesulfonate, 4-cyclohexylphenyldiphenylsulfonium camphorsulfonate, and 4-methanesulfonylphenyldiphenylsulfonium nonafluoro-n-butanesulfonate;

tetrahydrothiophenium salts such as 1-(4-n-butoxynaphthalen-1-yl)tetrahydrothiophenium trifluoromethanesulfonate, 1-(6-n-butoxynaphthalen-1-yl)tetrahydrothiophenium 2-bicyclo[2.2.1]hept-2-yl-1,1,2,2-tetrafluoroethane-1-sulfonate, and 1-(3,5-dimethyl-4-hydroxyphenyl)tetrahydrothiophenium camphorsulfonate;

iodonium salts such as diphenyliodonium trifluoromethanesulfonate, bis(4-t-butylphenyl)iodonium trifluoromethanesulfonate, bis(4-t-butylphenyl)iodonium nonafluoro-n-butanesulfonate, and 4-methoxyphenylphenyliodonium camphorsulfonate; and the like.

Examples of the N-sulfonyloxyimide compound include N-(trifluoromethylsulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

The acid generating agent (D) is preferably the onium salt compound, more preferably the iodonium salt, and still more preferably bis(4-t-butylphenyl)iodonium nonafluoro-n-butanesulfonate.

In the case in which the composition for forming a resist underlayer film contains the acid generating agent (D), the lower limit of a content of the acid generating agent (D) with respect to 100 parts by mass of the compound (A) is preferably 0.1 parts by mass, more preferably 0.5 parts by mass, still more preferably 1 part by mass, and particularly preferably 2 parts by mass. The upper limit of the content is preferably 30 parts by mass, more preferably 20 parts by mass, still more preferably 10 parts by mass, and particularly preferably 8 parts by mass. When the content of the acid generating agent (D) falls within the above range, solvent resistance of the resist underlayer film can be further improved.

### (E) Crosslinking Agent

The crosslinking agent (E) is a component capable of forming a crosslinking bond between components such as the compound (A) in the composition for forming a resist underlayer film, or capable of forming a cross-linked structure per se, by an action of heat or an acid. When the crosslinking agent (E) is contained in the composition for forming a resist underlayer film, solvent resistance of the resist underlayer film can be further improved.

The crosslinking agent is exemplified by a polyfunctional (meth)acrylate compound, an epoxy compound, a hydroxymethyl group-substituted phenol compound, an alkoxyalkyl group-containing phenol compound, a compound having an alkoxyalkylated amino group, and the like.

Examples of the polyfunctional (meth)acrylate compound include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, bis(2-hydroxyethyl)isocyanurate di(meth)acrylate, and the like.

Examples of the epoxy compound include novolac epoxy resins, bisphenol epoxy resins, alicyclic epoxy resins, aliphatic epoxy resins, and the like.

Examples of the hydroxymethyl group-substituted phenol compound include 2-hydroxymethyl-4,6-dimethylphenol, 1,3,5-trihydroxymethylbenzene, 3,5-dihydroxymethyl-4-methoxytoluene[2,6-bis(hydroxymethyl)-p-cresol], and the like.

An exemplary alkoxyalkyl group-containing phenol compound is a methoxymethyl group-containing phenol compound, an ethoxymethyl group-containing phenol compound, or the like.

The compound having an alkoxyalkylated amino group is exemplified by nitrogen-containing compounds having a plurality of active methylol groups in a molecule thereof wherein the hydrogen atom of the hydroxyl group of at least one of the methylol groups is substituted with an alkyl group such as a methyl group or a butyl group, and the like; examples thereof include (poly)methylolated melamines, (poly)methylolated glycolurils, (poly)methylolated benzoguanamines, (poly)methylolated ureas, and the like. It is to be noted that a mixture constituted with a plurality of substituted compounds may be used as the compound having an alkoxyalkylated amino group, and the compound having an alkoxyalkylated amino group may contain an oligomer component formed through partial self-condensation thereof.

The crosslinking agent (E) is preferably the compound having an alkoxyalkylated amino group, more preferably (poly)methylolated glycolurils, and still more preferably 1,3,4,6-tetrakis(methoxymethyl)glycoluril.

In the case in which the composition for forming a resist underlayer film contains the crosslinking agent (E), the lower limit of a content of the crosslinking agent (E) with respect to 100 parts by mass of the compound (A) is preferably 0.1 parts by mass, more preferably 1 part by mass, still more preferably 3 parts by mass, and particularly preferably 5 parts by mass. The upper limit of the content is preferably 50 parts by mass, more preferably 30 parts by mass, still more preferably 20 parts by mass, and particularly preferably 15 parts by mass. When the content of the crosslinking agent (E) falls within the above range, solvent resistance of the resist underlayer film can be further improved.

### Other Optional Component(s)

The other optional component(s) is/are exemplified by a surfactant, an adhesion aid, and the like.

### Preparation Procedure of Composition for Forming Resist Underlayer Film

The composition for forming a resist underlayer film may be prepared, for example, by mixing the compound (A), the polymer (B), and the organic solvent (C), as well as the optional component(s), which may be added as needed, in a certain ratio, and preferably filtering a thus resulting mixture through a membrane filter having a pore size of no greater than 0.2 μm.

### Resist Pattern-Forming Method

The resist pattern-forming method of another embodiment of the present invention includes: a step of applying a composition for forming a resist underlayer film directly or indirectly on an upper face side of a substrate to form a resist underlayer film (hereinafter, may be also referred to as “resist underlayer film-forming composition-applying step”); forming a silicon-containing film directly or indirectly on an upper face side of the resist underlayer film (hereinafter, may be also referred to as “silicon-containing film-forming step”); applying a composition for forming a resist film directly or indirectly on an upper face side of the silicon-containing film to form a resist film (hereinafter, may be also referred to as “resist film-forming composition-applying step”); exposing the resist film to a radioactive ray (hereinafter, may be also referred to as “exposing step”); and developing the resist film exposed (hereinafter, may be also referred to as “developing step”). In the resist pattern-forming method, the composition of the one embodiment of the present invention, described above, is used as the composition for forming a resist underlayer film.

According to the resist pattern-forming method, a favorable resist pattern can be formed by using the aforementioned resist underlayer film, being superior in the embedding property and flatness.

Hereinafter, each step will be described.

Resist Underlayer Film-Forming Composition-Applying Step

In this step, the composition of the one embodiment of the present invention is applied directly or indirectly on an upper face side of a substrate to form a resist underlayer film. Before the resist underlayer film-forming composition-applying step, the composition may be prepared. The composition may be prepared, for example, by mixing the compound (A), the polymer (B), and the organic solvent (C), as well as the optional component(s), which may be added as needed, in a certain ratio, and preferably filtering a thus resulting mixture through a membrane filter having a pore size of no greater than 0.2 μm.

The substrate is exemplified by a silicon wafer, a wafer coated with aluminum, and the like. Furthermore, an applying procedure of the composition is not particularly limited, and for example, an appropriate procedure such as spin coating, cast coating, or roll coating may be employed to enable forming of a coating film.

The coating film may be subjected to heating. The heating of the coating film is typically carried out in an ambient air, but may be carried out in a nitrogen atmosphere. The lower limit of a temperature in the heating is preferably 150° C., more preferably 200° C., and still more preferably 230° C. The upper limit of the temperature is preferably 600° C., more preferably 400° C., and still more preferably 300° C. The lower limit of a time period of the heating is preferably 15 sec, and more preferably 30 sec. The upper limit of the time period is preferably 1,200 sec, and more preferably 600 sec. Furthermore, the coating film may be exposed to a radioactive ray.

The lower limit of an average thickness of the resist underlayer film to be formed is preferably 30 nm, more preferably 50 nm, still more preferably 100 nm, and particularly preferably 150 nm. The upper limit of the average thickness is preferably 10,000 nm, more preferably 1,000 nm, still more preferably 500 nm, and particularly preferably 300 nm.

Silicon-Containing Film-Forming Step

In this step, a silicon-containing film is formed directly or indirectly on an upper face side of the resist underlayer film.

The silicon-containing film may be formed by applying a composition for silicon-containing film formation, a chemical vapor deposition (CVD) procedure, an atomic layer deposition (ALD) procedure, or the like. A procedure of forming the silicon-coating film by applying the composition for silicon-containing film formation is exemplified by applying the composition for silicon-containing film formation directly or indirectly on an upper face side of the resist underlayer film to form a coating film; and hardening the coating film by subjecting the coating film to an exposure and/or heating. As a commercially available product of the composition for silicon-containing film formation, for example, “NFC SOG01”, “NFC SOG04”, or “NFC SOG080” (all available from JSR Corporation), or the like may be used. A silicon oxide film, a silicon nitride film, a silicon oxynitride film, or an amorphous silicon film can be formed by the chemical vapor deposition (CVD) procedure or the atom layer deposition (ALD) procedure.

Examples of the radioactive ray which may be used for the exposure include: electromagnetic waves such as a visible light ray, an ultraviolet ray, a far ultraviolet ray, an X-ray, and a γ-ray; particle rays such as an electron beam, a molecular beam, and an ion beam; and the like.

The lower limit of a temperature when subjecting the coating film to heat is preferably 90° C., more preferably 150° C., and still more preferably 250° C. The upper limit of the temperature is preferably 550° C., more preferably 450° C., and still more preferably 350° C.

The lower limit of an average thickness of the silicon-containing film to be formed is preferably 1 nm, more preferably 10 nm, and still more preferably 30 nm. The upper limit of the average thickness is preferably 20,000 nm, more preferably 1,000 nm, and still more preferably 100 nm.

Resist Film-Forming Composition-Applying Step

In this step, the composition for forming a resist film is applied directly or indirectly on an upper face side of the silicon-containing film.

In this step, specifically, the resist film is formed by: applying the composition for forming a resist film to form a coating film such that a resultant resist film has a predetermined thickness, and subsequently subjecting the coating film to heating to evaporate away the solvent contained therein.

Examples of the composition for forming a resist film include a chemically amplified positive or negative resist composition that contains a radiation-sensitive acid generating agent; a positive resist composition containing an alkali-soluble resin and a quinone diazide-based photosensitizing agent; a negative resist composition containing an alkali-soluble resin and a crosslinking agent; and the like.

The lower limit of a proportion of all components other than the solvent in the composition for forming a resist film is preferably 0.3% by mass, and more preferably 1% by mass. The upper limit of the proportion is preferably 50% by mass, and more preferably 30% by mass. Moreover, the composition for forming a resist film is employed for forming the resist film, typically, after filtering through a filter having a pore size of no greater than 0.2 μm, for example. It is to be noted that in this step, a commercially available resist composition may be used directly.

A procedure for applying the composition for forming a resist film is exemplified by a spin-coating procedure and the like. A temperature when heating the coating film may be appropriately adjusted depending on the type of the composition for forming a resist film used. The lower limit of the temperature of the heating is preferably 30° C., and more preferably 50° C. The upper limit of the temperature is preferably 200° C., and more preferably 150° C. The lower limit of a time period of the heating is preferably 10 sec, and more preferably 30 sec. The upper limit of the time period is preferably 600 sec, and more preferably 300 sec.

Exposing Step

In this step, the resist film formed by the resist film-forming composition-applying step is exposed to a radioactive ray.

The radioactive ray for use in the exposure may be appropriately selected from: electromagnetic waves such as visible rays, ultraviolet rays, far ultraviolet rays, X-rays, and γ-rays; and particle rays such as electron beams, molecular beams, and ion beams in accordance with the type of the radiation-sensitive acid generating agent to be used in the composition for forming a resist film. Among these, far ultraviolet rays are preferred; and a KrF excimer laser beam (wavelength: 248 nm), an ArF excimer laser beam (wavelength: 193 nm), an extreme ultraviolet ray (EUV; wavelength: 13.5 nm, etc.), or an electron beam is more preferred.

Post-exposure heating may be carried out after the exposure for the purpose of improving resolution, pattern profile, developability, and the like. A temperature of the post-exposure heating may be appropriately adjusted depending on the type of the composition for forming a resist pattern used. The lower limit of the temperature of the post-exposure heating is preferably 50° C., and more preferably 70° C. The upper limit of the temperature is preferably 200° C., and more preferably 150° C. The lower limit of a time period of the post-exposure heating is preferably 10 sec, and more preferably 30 sec. The upper limit of the time period is preferably 600 sec, and more preferably 300 sec.

Developing Step

In this step, the resist film exposed is developed. The development may be either a development with an alkali or a development with an organic solvent. In the case of the development with an alkali, examples of the developer solution include basic aqueous solutions of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethyl ammonium hydroxide (TMAH), tetraethyl ammonium hydroxide, pyrrole, piperidine, choline, 1,8-diazabicyclo[5.4.0]-7-undecene, 1,5-diazabicyclo[4.3.0]-5-nonene, or the like. To the basic aqueous solution, a water-soluble organic solvent, e.g., alcohols such as methanol and ethanol, a surfactant, etc., may be added each in an appropriate amount. Alternatively, in the case of the development with an organic solvent, examples of the developer solution include various organic solvents exemplified as the organic solvent (C) of the composition for forming an underlayer resist film described above, and the like.

A predetermined resist pattern is formed by the development with the developer solution, followed by washing and drying.

Conducting etching using as a mask, the resist pattern formed by the resist pattern-forming method enables forming a pattern on the substrate.

The etching may be conducted once or multiple times. In other words, the etching may be conducted sequentially with patterns obtained by the etching as masks, and in light of obtaining a pattern having a more favorable shape, the etching is preferably conducted multiple times. In the case in which the etching is conducted multiple times, the silicon-containing film, the resist underlayer film, and the substrate are subjected to the etching sequentially in this order. An etching procedure may be exemplified by dry etching, wet etching, and the like. Of these, in light of the shape of the substrate pattern to be formed being more favorable, the dry etching is preferred. In the dry etching, for example, gas plasma such as oxygen plasma, or the like may be used.

### EXAMPLES

Hereinafter, the present invention will be explained in more detail by way of Examples, but the present invention is not in any way limited to these Examples. Various physical properties in the Examples were measured by the following methods.

Weight Average Molecular Weight (Mw)

The Mw of the polymer was determined by gel permeation chromatography (detector: differential refractometer) using GPC columns (“G2000 HXL”×2, “G3000 HXL”×1, and “G4000 HXL”×1; available from Tosoh Corporation), under analytical conditions involving a flow rate of 1.0 mL/min, an elution solvent of tetrahydrofuran, and a column temperature of 40° C., with mono-dispersed polystyrene as a standard.

Average Thickness of Film

The average thickness of the film was measured by using a spectroscopic ellipsometer (“M2000D,” available from J. A. WOOLLAM Co.).

### Synthesis of Compound (A)

As the compound (A), polymers (hereinafter, may be also referred to as “polymers (A-1) to (A-9)”) represented by the following formulae (A-1) to (A-9) were synthesized in accordance with the following procedure.

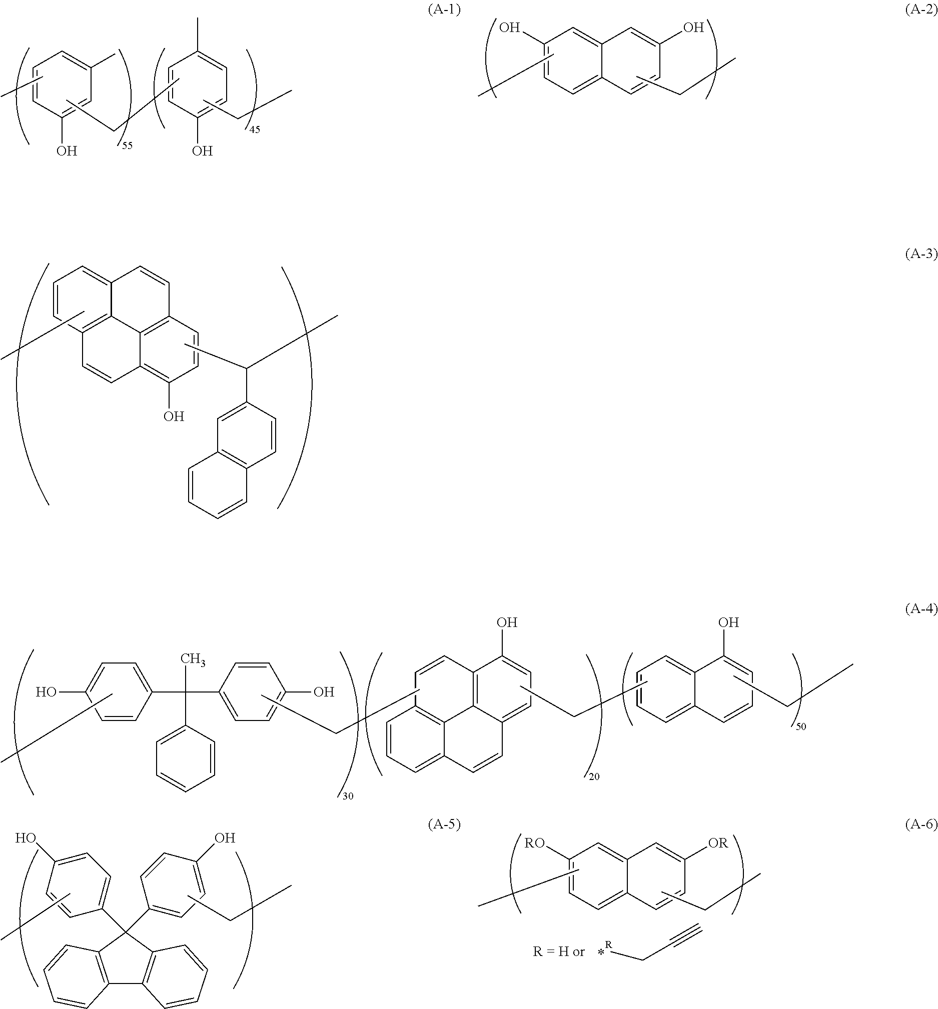

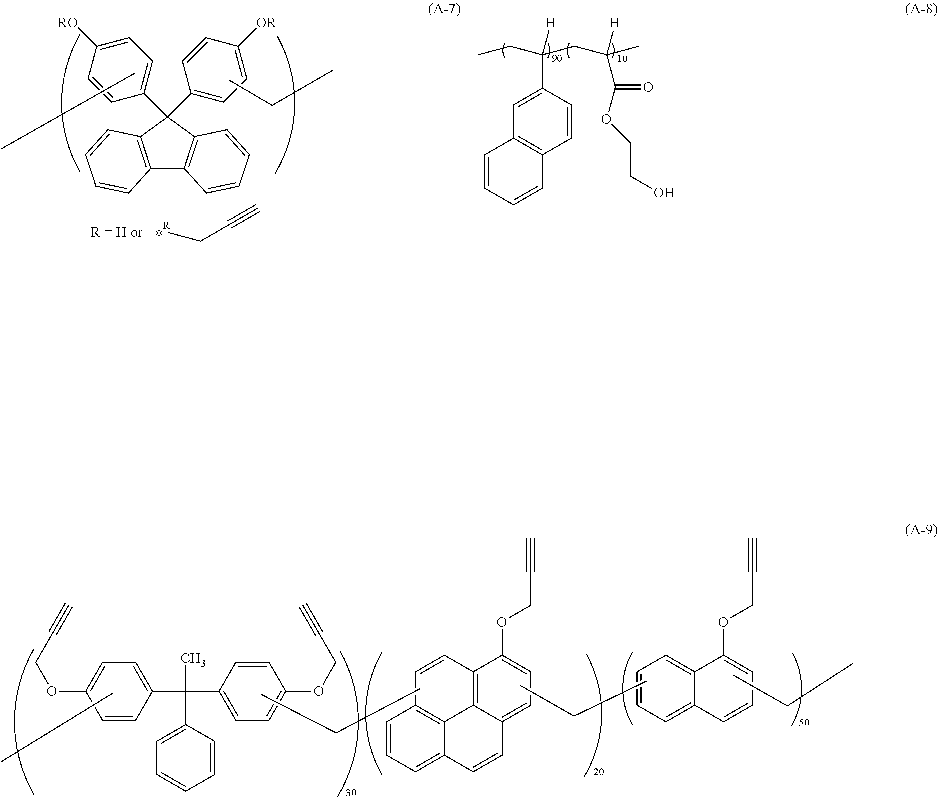

In the above formulae (A-6) and (A-7), *^{R} indicates a site to which an oxygen atom bonds.

In the above formulae (A-1), (A-4), (A-8), and (A-9), numbers appended to each structural unit indicate a proportion (mol %) of that structural unit.

### Synthesis Example 1-1 (Synthesis of Polymer (A-1))

Into a reaction vessel, 70 g of m-cresol, 57.27 g of p-cresol, 95.52 g of a 37% by mass aqueous formaldehyde solution, and 381.82 g of methyl isobutyl ketone were charged and dissolution was permitted in a nitrogen atmosphere. After a resulting solution was heated to 40° C., 2.03 g of p-toluenesulfonic acid was added thereto and a reaction was allowed at 85° C. for 4 hrs. The reaction liquid was cooled to 30° C. or below, and this reaction liquid was charged into a mixed solution of methanol/water (50/50 (mass ratio)) to permit reprecipitation. The precipitate was collected on a filter paper and then dried to give the polymer (A-1). The Mw of the polymer (A-1) was 50,000.

### Synthesis Example 1-2 (Synthesis of Polymer (A-2))

Into a reaction vessel, 150 g of 2,7-dihydroxynaphthalene, 76.01 g of a 37% by mass aqueous formaldehyde solution, and 450 g of methyl isobutyl ketone were charged and dissolution was permitted in a nitrogen atmosphere. After a resulting solution was heated to 40° C., 1.61 g of p-toluenesulfonic acid was added thereto and a reaction was allowed at 80° C. for 7 hrs. The reaction liquid was cooled to 30° C. or below, and this reaction liquid was charged into a mixed solution of methanol/water (50/50 (mass ratio)) to permit reprecipitation. The precipitate was collected on a filter paper and then dried to give the polymer (A-2). The Mw of the polymer (A-2) was 3,000.

### Synthesis Example 1-3 (Synthesis of Polymer (A-3))

Into a reaction vessel, 20 g of 1-hydroxypyrene, 7.16 g of 2-naphthaldehyde, and 82 g of propylene glycol monomethyl ether were charged and dissolution was permitted at room temperature in a nitrogen atmosphere. 8.81 g of methanesulfonate was added to a resulting solution, and the mixture was stirred at 120° C. for 12 hrs to conduct polymerization. After completion of the polymerization, the polymerization reaction liquid was charged into a large quantity of a mixed solution of methanol/water (80/20 (% by volume)), and collection of a thus obtained precipitate by filtering gave the polymer (A-3). The Mw of the polymer (A-3) was 1,100.

### Synthesis Example 1-4 (Synthesis of Polymer (A-4))

Into a reaction vessel, 15.2 g of 4,4′-(α-methylbenzylidene)bisphenol, 7.63 g of 1-hydroxypyrene, 12.6 g of 1-naphthol, and 4.52 g of paraformaldehyde were charged in a nitrogen atmosphere. Next, 60 g of propylene glycol monomethyl ether acetate was added to a resulting mixture and dissolution was permitted, followed by adding 0.220 g of p-toluenesulfonic acid monohydrate, and the mixture was stirred at 95° C. for 6 hrs to conduct polymerization. After completion of the polymerization, the polymerization reaction liquid was charged into a large quantity of a mixed solution of methanol/water (70/30 (mass ratio)), and collection of a thus obtained precipitate by filtering gave the polymer (A-4). The Mw of the polymer (A-4) was 3,363.

### Synthesis Example 1-5 (Synthesis of Polymer (A-5))

A polymer (A-5) was obtained in a similar manner to Synthesis Example 1-4, except that the 15.2 g of 4,4′-(α-methylbenzylidene)bisphenol, 7.63 g of 1-hydroxypyrene, 12.6 g of 1-naphthol, and 4.52 g of paraformaldehyde in Synthesis Example 1-4 were replaced with 37.9 g of bisphenolfluorene and 2.86 g of paraformaldehyde. The Mw of the polymer (A-5) was 4,500.

### Synthesis Example 1-6 (Synthesis of Polymer (A-6))

Into a reaction vessel, 20 g of the polymer (A-2) synthesized in Synthesis Example 1-2, 80 g of N,N-dimethylacetamide, and 22 g of potassium carbonate were charged in a nitrogen atmosphere. Next, a resulting solution was heated to 80° C., 19 g of propargyl bromide was added thereto, and a reaction was allowed for 6 hrs with stirring. Subsequently, to the reaction solution were added 40 g of methyl isobutyl ketone and 80 g of water and a liquid separation operation was conducted. Thereafter, an organic phase thus obtained was charged into a large quantity of methanol and a thus obtained precipitate was collected by filtering to give the polymer (A-6). The Mw of the polymer (A-6) was 3,200.

### Synthesis Example 7: Synthesis of Polymer (A-7)

Into a reaction vessel, 20 g of the polymer (A-5) synthesized in Synthesis Example 1-5, 80 g of N,N-dimethylacetamide, and 22 g of potassium carbonate were charged in a nitrogen atmosphere. Next, a resulting solution was heated to 80° C., 19 g of propargyl bromide was added thereto, and a reaction was allowed for 6 hrs with stirring. Thereafter, to the reaction solution were added 40 g of methyl isobutyl ketone and 80 g of water and a liquid separation operation was conducted, followed by charging an organic phase thus obtained into a large quantity of methanol and collecting a thus obtained precipitate by filtering to give the polymer (A-7). The Mw of the polymer (A-7) was 4,800.

### Synthesis Example 1-8 (Synthesis of Polymer (A-8))

In a reaction vessel, dissolution of 35 g of 2-vinylnaphthylene and 2.9 g of 2-hydroxyethyl acrylate in 112 g of cyclohexanone was followed by carrying out replacement with nitrogen in the reaction vessel and heating to 60° C. 1.9 g of azobisisobutyronitrile dissolved in 47 g of cyclohexanone was added thereto, and a reaction was allowed at 60° C. for 24 hrs. The reaction solution was cooled and then charged into methanol to permit reprecipitation, and a precipitate thus obtained was dried to give the polymer (A-8). The Mw of the polymer (A-8) was 11,000.

### Synthesis Example 1-9 (Synthesis of Polymer (A-9))

Into a reaction vessel, 20 g of the polymer (A-4) synthesized in Synthesis Example 1-4 and 18.9 g of potassium carbonate were charged in a nitrogen atmosphere. Next, a resulting solution was heated to 80° C., 35.3 g of propargyl bromide was added thereto, and a reaction was allowed for 6 hrs with stirring. Thereafter, to the reaction solution were added 40 g of methyl isobutyl ketone and 80 g of water, and a liquid separation operation was conducted. Thereafter an organic phase thus obtained was charged into a large quantity of methanol and a thus obtained precipitate was collected by filtering to give the polymer (A-9). The Mw of the polymer (A-9) was 3,820.

### Synthesis of Polymer (B)

As the polymer (B), polymers (hereinafter, may be also referred to as “polymers (B-1) to (B-4)”) represented by the following formulae (B-1) to (B-4) were synthesized in accordance with the following procedures.

### Synthesis Example 2-1 (Synthesis of Polymer (B-1)

73.5 g of 1,1,1,3,3,3-hexafluoroisopropyl methacrylate and 26.5 g of 2-ethylhexyl methacrylate were dissolved in 100 g of 2-butanone, and 5.1 g of dimethyl 2,2′-azobis(2-methylpropionate) was added thereto to prepare a monomer solution. Into a reaction vessel, 100 g of 2-butanone was charged in a nitrogen atmosphere and heated to 80° C., and the monomer solution was added thereto dropwise over 3 hrs with stirring. The time of the start of the dropwise addition was regarded as the time of the start of the polymerization reaction, and the polymerization reaction was allowed to proceed for 6 hrs, followed by cooling to 30° C. or below. To the reaction solution was added 300 g of propylene glycol monomethyl ether acetate, and 2-butanone was removed by concentration under reduced pressure to give a propylene glycol monomethyl ether acetate solution of the polymer (B-1). The Mw of the polymer (B-1) was 12,000, and the Mw/Mn was 2.1.

### Synthesis Examples 2-2 to 2-4 (Synthesis of Polymers (B-2) to (B-4))

Except for using each compound that gives each structural unit in each proportion (mol %) shown in the following formulae (B-2) to (B-4), propylene glycol monomethyl ether acetate solutions of polymers (B-2) to (B-4) were obtained in a similar manner to Synthesis Example 2-1. The Mw of the polymer (B-2) was 12,500, and the Mw/Mn was 2.0. The Mw of the polymer (B-3) was 11,000, and the Mw/Mn was 2.1. The Mw of the polymer (B-4) was 13,000, and the Mw/Mn was 2.2.

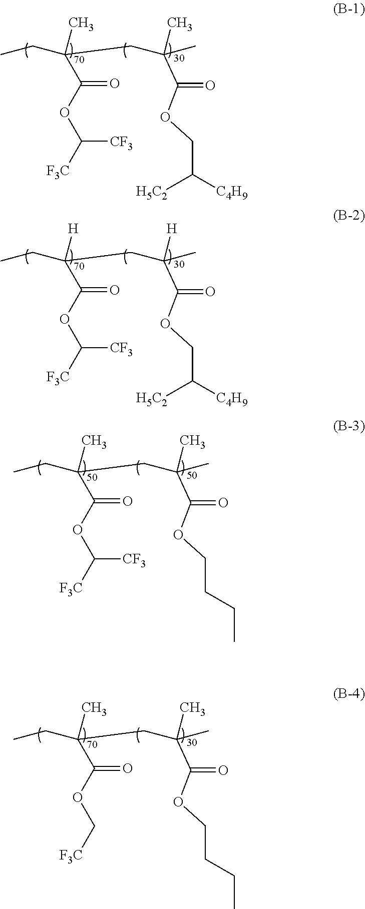

In the above formulae (B-1) to (B-4), numbers appended to each structural unit indicate a proportion (mol %) of that structural unit.

### Preparation of Composition for Forming Resist Underlayer Film

The organic solvent (C), the acid generating agent (D), and the crosslinking agent (E) used in preparing the composition for forming a resist underlayer film are as shown below.

(C) Organic Solvent

C-1: propylene glycol monomethyl ether acetate

(D) Acid Generating Agent

D-1: bis(4-t-butylphenyl)iodonium nonafluoro-n-butanesulfonate (a compound represented by the following formula (D-1))

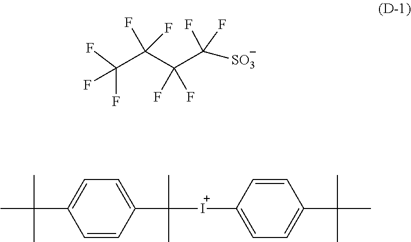

(E) Crosslinking Agent

E-1: 1,3,4,6-tetrakis(methoxymethyl)glycoluril (a compound represented by the following formula (E-1))

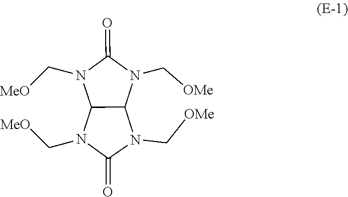 [SMILES: COCN1C(=O)N(COC)C2C1N(COC)C(=O)N2COC]

### Example 1

100 parts by mass of (A-1) as the compound (A), 30 parts by mass (excluding the propylene glycol monomethyl ether acetate solvent) of (B-1) as the polymer (B), and 1,300 parts by mass of (C-1) as the organic solvent (C) (including the propylene glycol monomethyl ether acetate solvent in the polymer (B) solution) were mixed together, and a thus obtained mixture was filtered through a filter having a pore size of 0.2 μm to give a composition for forming a resist underlayer film (J-1).

### Examples 2 to 26 and Comparative Examples 1 to 9

Compositions for forming resist underlayer films (J-2) to (J-26) and (CJ-1) to (CJ-9) were prepared in a similar manner to Example 1, except that for each component, the type and content shown in Table 1 were used.

TABLE 1

| | Composition | | | | | | | (D) Acid generating | | (E) Crosslinking | |
|---|---|---|---|---|---|---|---|---|---|---|---|
| | for forming | (A) Compound | | (B) Polymer | | (C) Organic solvent | | agent | | agent | |
| | resist under- | | content (parts | | content (parts | | content (parts | | content (parts | | content (parts |
| — | layer film | type | by mass) | type | by mass) | type | by mass) | type | by mass) | type | by mass) |
| Example 1 | J-1 | A-1 | 100 | B-1 | 30 | C-1 | 1,300 | — | — | — | — |
| Example 2 | J-2 | A-2 | 100 | B-1 | 30 | C-1 | 1,300 | — | — | — | — |
| Example 3 | J-3 | A-3 | 100 | B-1 | 30 | C-1 | 1,300 | — | — | — | — |
| Example 4 | J-4 | A-4 | 100 | B-1 | 30 | C-1 | 1,300 | — | — | — | — |
| Example 5 | J-5 | A-5 | 100 | B-1 | 30 | C-1 | 1,300 | — | — | — | — |
| Example 6 | J-6 | A-6 | 100 | B-1 | 30 | C-1 | 1,300 | — | — | — | — |
| Example 7 | J-7 | A-7 | 100 | B-1 | 30 | C-1 | 1,300 | — | — | — | — |
| Example 8 | J-8 | A-8 | 100 | B-1 | 30 | C-1 | 1,300 | — | — | — | — |
| Example 9 | J-9 | A-9 | 100 | B-1 | 30 | C-1 | 1,300 | — | — | — | — |
| Example 10 | J-10 | A-1 | 100 | B-2 | 30 | C-1 | 1,300 | — | — | — | — |
| Example 11 | J-11 | A-2 | 100 | B-2 | 30 | C-1 | 1,300 | — | — | — | — |
| Example 12 | J-12 | A-3 | 100 | B-2 | 30 | C-1 | 1,300 | — | — | — | — |
| Example 13 | J-13 | A-4 | 100 | B-2 | 30 | C-1 | 1,300 | — | — | — | — |
| Example 14 | J-14 | A-1 | 100 | B-3 | 30 | C-1 | 1,300 | — | — | — | — |
| Example 15 | J-15 | A-2 | 100 | B-3 | 30 | C-1 | 1,300 | — | — | — | — |
| Example 16 | J-16 | A-3 | 100 | B-3 | 30 | C-1 | 1,300 | — | — | — | — |
| Example 17 | J-17 | A-4 | 100 | B-3 | 30 | C-1 | 1,300 | — | — | — | — |
| Example 18 | J-18 | A-1 | 100 | B-4 | 30 | C-1 | 1,300 | — | — | — | — |
| Example 19 | J-19 | A-2 | 100 | B-4 | 30 | C-1 | 1,300 | — | — | — | — |
| Example 20 | J-20 | A-3 | 100 | B-4 | 30 | C-1 | 1,300 | — | — | — | — |
| Example 21 | J-21 | A-4 | 100 | B-4 | 30 | C-1 | 1,300 | — | — | — | — |
| Example 22 | J-22 | A-1 | 100 | B-1 | 5 | C-1 | 1,050 | — | — | — | — |
| Example 23 | J-23 | A-1 | 100 | B-1 | 10 | C-1 | 1,100 | — | — | — | — |
| Example 24 | J-24 | A-1 | 100 | B-1 | 50 | C-1 | 1,500 | D-1 | 4 | E-1 | 10 |
| Example 25 | J-25 | A-1 | 100 | B-1 | 100 | C-1 | 2,000 | — | — | — | — |
| Example 26 | J-26 | A-1 | 100 | B-1 | 150 | C-1 | 2,500 | — | — | — | — |
| Comparative | CJ-1 | A-1 | 100 | — | — | C-1 | 1,000 | — | — | — | — |
| Example 1 | | | | | | | | | | | |
| Comparative | CJ-2 | A-2 | 100 | — | — | C-1 | 1,000 | — | — | — | — |
| Example 2 | | | | | | | | | | | |
| Comparative | CJ-3 | A-3 | 100 | — | — | C-1 | 1,000 | — | — | — | — |
| Example 3 | | | | | | | | | | | |
| Comparative | CJ-4 | A-4 | 100 | — | — | C-1 | 1,000 | — | — | — | — |
| Example 4 | | | | | | | | | | | |
| Comparative | CJ-5 | A-5 | 100 | — | — | C-1 | 1,000 | — | — | — | — |
| Example 5 | | | | | | | | | | | |
| Comparative | CJ-6 | A-6 | 100 | — | — | C-1 | 1,000 | — | — | — | — |
| Example 6 | | | | | | | | | | | |
| Comparative | CJ-7 | A-7 | 100 | — | — | C-1 | 1,000 | — | — | — | — |
| Example 7 | | | | | | | | | | | |
| Comparative | CJ-8 | A-8 | 100 | — | — | C-1 | 1,000 | — | — | — | — |
| Example 8 | | | | | | | | | | | |
| Comparative | CJ-9 | A-9 | 100 | — | — | C-1 | 1,000 | — | — | — | — |
| Example 9 | | | | | | | | | | | |

### Evaluations

With regard to each of the compositions for forming a resist underlayer film prepared as described above, a resulting resist underlayer film was evaluated by the following methods on an embedding property and flatness. The results of the evaluations are shown in Table 2 below.

Embedding Property

Each composition for forming a resist underlayer film prepared as described above was applied by a spin-coating procedure using a spin coater (“CLEAN TRACK ACT-12,” available from Tokyo Electron Limited), on a silicon substrate having formed thereon a line-and-space pattern with a depth of 100 nm and a width of 100 nm. Subsequently, by heating in an ambient air atmosphere at 250° C. for 60 sec followed by cooling at 23° C. for 60 sec, a resist underlayer film having an average thickness of 200 nm at line pattern parts was formed. Accordingly, a resist underlayer film-attached silicon substrate was obtained. A cross-sectional shape of the resist underlayer film-attached silicon substrate was observed by using a scanning electron microscope (“S-4800,” available from Hitachi High-Technologies Corporation), and the embedding property was evaluated. The embedding property was evaluated to be: “A” (favorable) in a case in which the resist underlayer film was embedded to a bottom part of the space pattern; and “B” (unfavorable) in a case in which the resist underlayer film was not embedded to the bottom part of the space pattern.

Flatness

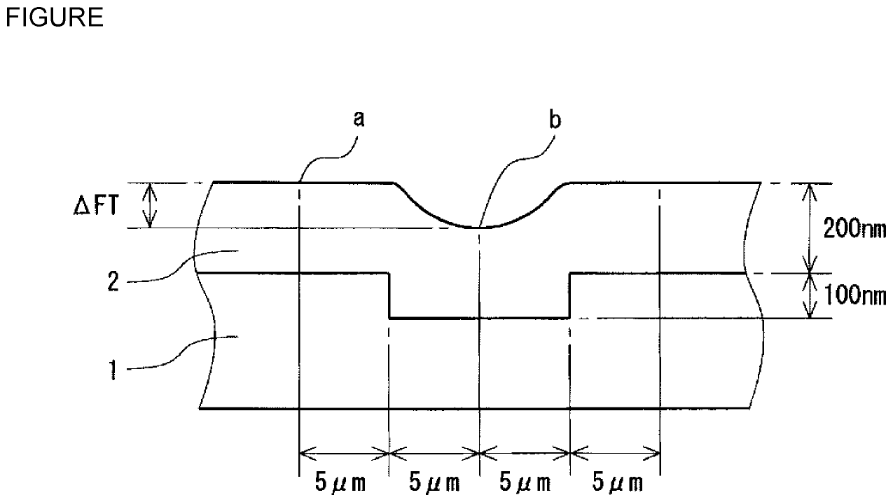

Each of the compositions for forming resist underlayer films prepared as described above was applied by a spin-coating procedure using a spin coater (“CLEAN TRACK ACT-12” available from Tokyo Electron Limited), on a silicon substrate 1 provided with a trench pattern having a depth of 100 nm and a groove width of 10 μm formed thereon, as shown in the FIGURE. Subsequently, by heating in an ambient air atmosphere at 250° C. for 60 sec followed by cooling at 23° C. for 60 sec, a resist underlayer film 2 was formed having an average thickness of 200 nm at parts having no trench provided. Accordingly, a resist underlayer film-attached silicon substrate was obtained. A cross-sectional shape of the resist film-attached silicon substrate was observed by using a scanning electron microscope (“S-4800,” available from Hitachi High-Technologies Corporation), and the difference (AFT) between a height at a center portion “b” of the trench pattern of the resist underlayer film 2 and a height at a position “a” 5 μm away from the edge of the trench pattern, at which no trench pattern was provided, was defined as a marker of the flatness. The flatness was evaluated to be: “A” (favorable) in a case of AFT being less than 30 nm; and “B” (unfavorable) in a case of AFT being no less than 30 nm. It is to be noted that the difference in heights shown in the FIG. 1s exaggerated.

TABLE 2

| | Composition for | | |
|---|---|---|---|
| | forming resist | Embedding | |
| — | underlayer film | property | Flatness |
| Example 1 | J-1 | A | A |
| Example 2 | J-2 | A | A |
| Example 3 | J-3 | A | A |
| Example 4 | J-4 | A | A |
| Example 5 | J-5 | A | A |
| Example 6 | J-6 | A | A |
| Example 7 | J-7 | A | A |
| Example 8 | J-8 | A | A |
| Example 9 | J-9 | A | A |
| Example 10 | J-10 | A | A |
| Example 11 | J-11 | A | A |
| Example 12 | J-12 | A | A |
| Example 13 | J-13 | A | A |
| Example 14 | J-14 | A | A |
| Example 15 | J-15 | A | A |
| Example 16 | J-16 | A | A |
| Example 17 | J-17 | A | A |
| Example 18 | J-18 | A | A |
| Example 19 | J-19 | A | A |
| Example 20 | J-20 | A | A |
| Example 21 | J-21 | A | A |
| Example 22 | J-22 | A | A |
| Example 23 | J-23 | A | A |
| Example 24 | J-24 | A | A |
| Example 25 | J-25 | A | A |
| Example 26 | J-26 | A | A |
| Comparative | CJ-1 | A | B |
| Example 1 | | | |
| Comparative | CJ-2 | A | B |
| Example 2 | | | |
| Comparative | CJ-3 | A | B |
| Example 3 | | | |
| Comparative | CJ-4 | A | B |
| Example 4 | | | |
| Comparative | CJ-5 | A | B |
| Example 5 | | | |
| Comparative | CJ-6 | A | B |
| Example 6 | | | |
| Comparative | CJ-7 | A | B |
| Example 7 | | | |
| Comparative | CJ-8 | A | B |
| Example 8 | | | |
| Comparative | CJ-9 | A | B |
| Example 9 | | | |

As is seen from the results shown in Table 2, the compositions for forming resist underlayer films of the Examples enable forming resist underlayer films which are superior in the embedding property and flatness.

According to the composition for forming a resist underlayer film of the one embodiment of the present invention, a resist underlayer film superior in the embedding property and flatness can be formed. The resist underlayer film of the embodiment of the present invention is superior in the embedding property and flatness. According to the resist pattern-forming method of the another embodiment of the present invention, a favorable resist pattern can be formed by using such a resist underlayer film, being superior in the embedding property and flatness. Therefore, these can be suitably used in the manufacture of semiconductor devices and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A composition comprising:
an aromatic ring-containing compound;
a fluorine atom-containing polymer; and
an organic solvent, wherein
the fluorine atom-containing polymer comprises: a first structural unit represented by formula (1); and a second structural unit represented by formula (2): 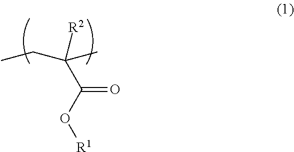
wherein,
in the formula (1), R¹ represents a fluorine atom-containing monovalent organic group having 1 to 20 carbon atoms; and R² represents a hydrogen atom or a monovalent hydrocarbon group having 1 to 20 carbon atoms, and 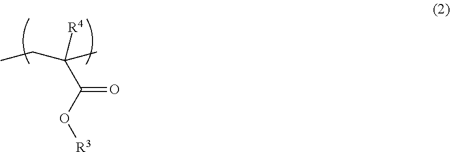
in the formula (2), R³ represents a monovalent hydrocarbon group having 1 to 20 carbon atoms; and R⁴ represents a hydrogen atom or a monovalent hydrocarbon group having 1 to 20 carbon atoms.

2. The composition according to claim 1, wherein a proportion of the first structural unit with respect to total structural units constituting the fluorine atom-containing polymer is no less than 1 mol % and no greater than 80 mol %.

3. The composition according to claim 1, wherein a proportion of the second structural unit with respect to total structural units constituting the fluorine atom-containing polymer is no less than 10 mol % and no greater than 99 mol %.

4. The composition according to claim 2, wherein a content of the fluorine atom-containing polymer with respect to 100 parts by mass of the aromatic ring-containing compound is no less than 1 part by mass and no greater than 200 parts by mass.

5. The composition according to claim 4, wherein the aromatic ring-containing compound is a polymer comprising an aromatic ring-containing structural unit.

6. The composition according to claim 5, wherein the polymer comprising the aromatic ring-containing structural unit is a novolac resin, a resol resin, a styrene resin, an acenaphthylene resin, an indene resin, an arylene resin, a triazene resin, a calixarene resin, or a combination thereof.

7. The composition according to claim 5, wherein in the formula (2), R³ represents an alkyl group.

8. The composition according to claim 6, wherein in the formula (2), R³ represents an alkyl group.

9. The composition according to claim 8, wherein in the formula (1), R¹ represents a fluorinated alkyl group.

10. A resist pattern-forming method comprising:
applying directly or indirectly on an upper face side of a substrate, the composition according to claim 1 to form a resist underlayer film;
forming a silicon-containing film directly or indirectly on an upper face side of the resist underlayer film;
applying a composition for forming a resist film directly or indirectly on an upper face side of the silicon-containing film to form a resist film;
exposing the resist film to a radioactive ray; and
developing the resist film exposed.

11. The resist pattern-forming method according to claim 10, wherein a proportion of the first structural unit with respect to total structural units constituting the fluorine atom-containing polymer is no less than 1 mol % and no greater than 80 mol %.

12. The resist pattern-forming method according to claim 10, wherein a proportion of the second structural unit with respect to total structural units constituting the fluorine atom-containing polymer is no less than 10 mol % and no greater than 99 mol %.

13. The resist pattern-forming method according to claim 11, wherein a content of the fluorine atom-containing polymer with respect to 100 parts by mass of the aromatic ring-containing compound is no less than 1 part by mass and no greater than 200 parts by mass.

14. The resist pattern-forming method according to claim 13, wherein the aromatic ring-containing compound is a polymer comprising an aromatic ring-containing structural unit.

15. The resist pattern-forming method according to claim 14, wherein the polymer comprising the aromatic ring-containing structural unit is a novolac resin, a resol resin, a styrene resin, an acenaphthylene resin, an indene resin, an arylene resin, a triazene resin, a calixarene resin, or a combination thereof.

16. The resist pattern-forming method according to claim 14, wherein in the formula (2), R³ represents an alkyl group.

17. The resist pattern-forming method according to claim 15, wherein in the formula (2), R³ represents an alkyl group.

18. The composition according to claim 17, wherein in the formula (1), R¹ represents a fluorinated alkyl group.
